(19) United States
(12) Patent Application Publication
(10) Pub. No.: US 2026/0165111 A1
(43) Pub. Date: Jun. 11, 2026

(54) Semiconductor Device Metallization Contact Structure and Method

(71) Applicant: Infineon Technologies Austria AG, Villach (AT)

(72) Inventors: Manuel Vorwerk, Villach (AT); Markus Augustin, Hutthurm (DE); Klaus Goller, Regensburg (DE); Bhargav Pandya, Gilbert, AZ (US)

(21) Appl. No.: 19/414,880

(22) Filed: Dec. 10, 2025

Related U.S. Application Data
(60) Provisional application No. 63/730,556, filed on Dec. 11, 2024.

(51) Int. Cl. H10W 20/44; H10D 30/01; H10D 30/47; H10D 62/824; H10W 20/00; H10W 20/41; H10W 20/42; H10W 20/48

(52) U.S. Cl. CPC H10W 20/4421; H10D 30/015; H10D 30/475; H10D 62/824; H10W 20/045; H10W 20/082; H10W 20/084; H10W 20/422; H10W 20/435; H10W 20/48

(57) ABSTRACT

A semiconductor device includes a semiconductor substrate, a power semiconductor device monolithically formed in the semiconductor substrate, and an electrical interconnect region formed on an upper surface of the semiconductor substrate. The semiconductor device includes an upper-level contact pad formed in an uppermost level of metallization from the electrical interconnect region, wherein a plurality of external contact structures is formed on the upper-level contact pad. Additionally, the semiconductor device includes a hybrid via-metallization structure pad formed in a lower part of an interconnect region and forming a via structure with a terminal of the power semiconductor device and an interconnect metallization.

### BACKGROUND

ECD (electrochemical deposition) process steps are often used to form bond metallization and bond pad structures in semiconductor devices. For example, nickel phosphorus plating (NiP) formed by electroless processing can be used to enable a wide range of interconnect options, e.g., nail head bonding, wedge bonding, flip chip bonding, etc., in semiconductor devices. While advantageous in many respects, NiP is subject to phase transformation from an amorphous state to a crystalline state when subjected to high temperatures for extended durations. The crystalline state of NiP is more brittle and hence may lead to cracking and other reliability issues. Many different processing steps such as steps for forming interconnect metallization/dielectrics and so-called back-end processes such as soldering and die attach involve significant thermal budgets that may be problematic for these NiP structures as they may transform the material into the crystalline state, which makes the material more brittle. Additionally, mechanical forces from wire bonding and and further thermomechanical forces during the lifetime of the device may lead to failure. It is desirable to form semiconductor devices with bond pad structures that facilitate a wide range of interconnect options, are mechanically durable, and can be produced at low cost and complexity.

Many applications such as automotive and industrial applications utilize power electronic circuitry such as IGBTs (insulated gate bipolar transistors), power MOSFETs (metal oxide semiconductor field effect transistors), power diodes, etc. For example, common power circuits include single and multi-phase half-wave rectifiers, single and multi-phase full-wave rectifiers, voltage regulators, etc. In these power circuits, the devices are designed to withstand voltages on the order of 100V, 200V, 600V, 1200V or more. Every power application requires a so-called driver-logic to control the discrete power devices which form the power circuits. In an integrated device solution, the driver-logic is formed on the same chip as the power device, thereby reducing parasitic and extra manufacturing costs associated with a two-chip solution. However, this solution uses valuable die area in an expensive material technology, e.g., GaN, SiC, for the logic device, which does not have the same performance requirements. It therefore desirable to provide driver-logic together with power device logic at a high degree of integration, small area size, and relatively low area consumption by the driver-logic. In particular, the planarity of the contact to the wide bandgap component leverages decisive advantages for power semiconductors in terms of the reliability of the contacts and the connected metallic layers. Power semiconductors handle high currents and, in the case of planar contacts, can achieve a homogeneous distribution of the current density across the contact surface without current crowding in non-planar or adjacent areas of the contact construction. This homogeneous current distribution and low-resistance contact is a prerequisite for the high strength against electromigration of the metals used under current load.

### SUMMARY

A semiconductor device is disclosed. According to an embodiment, the semiconductor device comprises a semiconductor substrate, a power semiconductor device monolithically formed in the semiconductor substrate, an electrical interconnect region formed on an upper surface of the semiconductor substrate, a first upper-level contact pad formed in an uppermost level of metallization from the electrical interconnect region, the first upper-level contact pad being electrically connected with a first load terminal of the power semiconductor device, a passivation structure formed over the electrical interconnect region and partially covering the first upper-level contact pad, an imide layer formed over outer corners of the first upper-level contact pad and exposing a central region of the first upper-level contact pad, and a plurality of external contact structures that are exposed from openings in the passivation structure in the central region of the first upper-level contact pad, wherein the external contact structures each comprise NiP.

According to another embodiment, the semiconductor device comprises a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface, and a high-electron mobility transistor monolithically formed in the semiconductor substrate and comprising first and second load terminals, a first interlayer dielectric region formed over an upper surface of the semiconductor substrate, and a first interconnect metallization level formed over the first interlayer dielectric region, and a hybrid via-metallization structure in low-ohmic contact with the first load terminal of the high-electron mobility transistor, wherein the hybrid via-metallization structure is a continuous metal structure that comprises a via portion arranged within a trench in the first interlayer dielectric region and a metallization portion arranged over the via portion.

A method of forming a semiconductor device is disclosed. According to an embodiment, the method comprises providing a semiconductor substrate with a power semiconductor device monolithically formed in the semiconductor substrate, forming an electrical interconnect region formed on an upper surface of the semiconductor substrate, the electrical interconnect region comprising a first upper-level contact pad formed in an uppermost level of metallization from the electrical interconnect region and being electrically connected with a first load terminal of the power semiconductor device, forming a passivation structure over the electrical interconnect region and partially covering the first upper-level contact pad, forming an imide layer over corners of the first upper-level contact pad and exposing a central region of the first upper-level contact pad, forming a plurality of external contact structures that are exposed from openings in the passivation structure in the central region of the first upper-level contact pad, wherein the external contact structures each comprise NiP.

According to an embodiment, the method comprises providing semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface, monolithically forming a high-electron mobility transistor in the semiconductor substrate and comprising first and second load terminals;

forming a first interlayer dielectric region over an upper surface of the semiconductor substrate, forming a first interconnect metallization level over the first interlayer dielectric region, and forming a hybrid via-metallization structure in low-ohmic contact with the first load terminal of the high-electron mobility transistor, wherein the hybrid via-metallization structure is a continuous metal structure that comprises a via portion arranged within a trench in the first interlayer dielectric region and a metallization portion arranged over the via portion.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial cross-sectional view of a semiconductor device that comprises a plurality of external contact structures, according to an embodiment.

FIG. 2 illustrates a plan-view of a semiconductor device that comprises a plurality of external contact structures, according to an embodiment.

FIG. 3, which includes FIGS. 3A-3C, illustrates a cross-sectional view of a method of forming a semiconductor device that comprises a plurality of external contact structures, according to an embodiment.

FIG. 4 illustrates a partial cross-sectional view of a semiconductor device that comprises a hybrid via-metallization structure, according to an embodiment.

FIG. 5 illustrates a partial cross-sectional view of a semiconductor device that comprises a hybrid via-metallization structure with a dielectric spacer, according to an embodiment.

### DETAILED DESCRIPTION

Described herein are embodiments of a semiconductor device with a thick upper-level contact pad with a plurality of external contact structures disposed thereon. The external contact structures are formed by an electrochemical deposition and comprise NiP. The external contact structures are formed in a pattern that facilitates electrical interconnect, nail head bonding, wedge bonding, flip chip bonding, etc. Advantageously, the external contact structures are arranged to permit expansion, lateral movement, etc., while preventing the risk of failure. In particular, the external contact structures are arranged in a mushroom-like arrangement with a lateral overlap around openings in a passivation structure. Additionally, an imide layer is formed over the edge sides of the upper-level contact pads such that the imide layer is laterally spaced apart from the external contact structures. The imide layer is formed before the external contact structures. This prevents the external contact structures from being exposed to the thermal budget associated with the imide layer curing process and therefore mitigates the NiP from becoming brittle because of this curing process.

Described herein are embodiments of a semiconductor device with a hybrid via-metallization structure formed at a lower level of the interconnect region. The hybrid via-metallization structure is a continuous metal structure that forms both a lower-level via structure that forms an ohmic contact with a device terminal and an interconnect metallization structure that is used for electrical routing and/or a connection with an upper-level contact pad. According to an embodiment, the hybrid via-metallization structure is formed by a dual damascene process whereby the continuous metal structure is created from a single metal deposition step. The hybrid via-metallization structure facilitates higher integration density and lower contact resistance in comparison to previously known via and metallization techniques. This can be beneficially leveraged to reduce area consumption, which can be particularly advantageous in the context of an integrated device with a power transistor and driver device formed in an expensive material technology, such as GaN or SiC. In an embodiment, spacer dielectric regions are provided at lower corners of the hybrid via-metallization structure. This can improve the planarity and integrity of the lower contacting surface of the hybrid via-metallization structure, which in turn facilitates higher integration density.

The semiconductor device embodiments disclosed herein may be implemented in an integrated device solution wherein the driver-logic is formed on the same chip as the power device. In particular, the semiconductor device embodiments disclosed herein may be implemented in a device that comprises a GaN-based HEMT and an Si based gate driver, along with additional circuitry for matching the Si based gate driver with the GaN-based HEMT. An example of such a device is disclosed in US Patent Publication 2019/0326280 A1, the content of which is incorporated by reference herein in its entirety. The metallization structures disclosed herein can be used to provide a reduced set of key features in a very area efficient way.

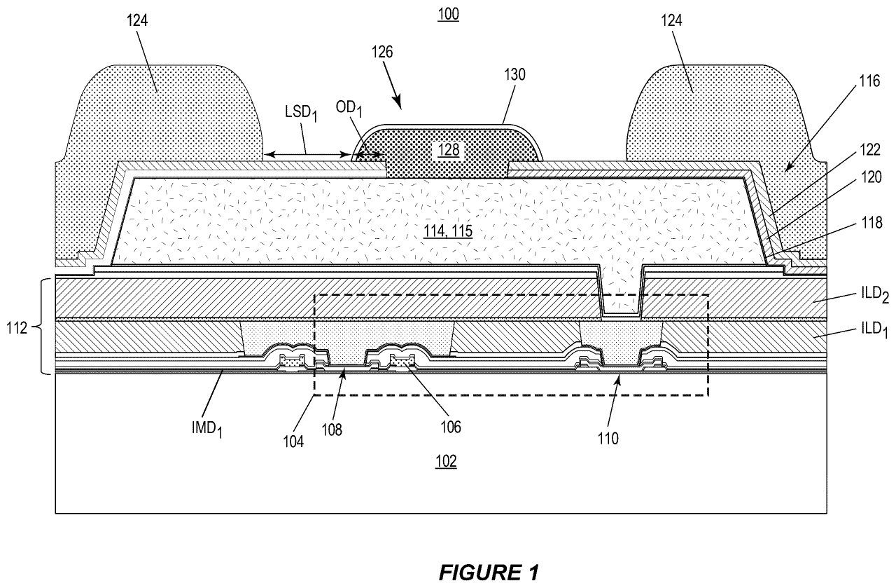

FIG. 1 illustrates a partial cross-sectional view of a semiconductor device 100, according to an embodiment. The semiconductor device 100 comprises a semiconductor substrate 102. The semiconductor substrate 102 may comprise any type of semiconductor material such as Si, SiC, GaN, etc. The semiconductor substrate 102 may include a base semiconductor and one or more epitaxial layers grown on the base semiconductor. The semiconductor substrate 102 may comprise one or more transistor devices monolithically formed therein. For example, the semiconductor device 100 may comprise one or more power devices monolithically formed in the semiconductor substrate 102. In the depicted embodiment, the semiconductor device 100 comprises a lateral transistor 104 that comprises a gate electrode 106 arranged between drain 110 and source 108 electrodes, wherein the gate electrode 106 is configured to control a conductive connection between the drain and source electrodes 110, 108 in a commonly known manner. According to an embodiment, the lateral transistor 104 is configured as a HEMT device. In that case, the semiconductor substrate 102 comprises one or more heterojunction interfaces between regions of type III-V material with different bandgaps (e.g., GaN and AlGaN), and the channel of the device is provided from a naturally occurring two-dimensional charge carrier gas, i.e., a 2DEG or 2DHG. More generally, the semiconductor device 100 may comprise any of a wide range of power devices monolithically integrated into the semiconductor substrate 102. A power device refers to a device that is rated to accommodate voltages of at least 100 V (volts), and more typically voltages of 600 V, 1200 V or more and/or is rated to accommodate currents of at least 1 A, and more typically currents of 10 A, 50 A, 100 A or more. Examples of power devices include MOSFETs (Metal Oxide Semiconductor Field Effect Transistors), IGBTs (Insulated Gate Bipolar Transistors), and HEMTs (High Electron Mobility Transistors), etc. Separately or in combination, the semiconductor device 100 may include other types of devices, e.g., logic devices, driver devices, passive elements, etc. monolithically integrated into the semiconductor substrate 102.

The semiconductor device 100 comprises an electrical interconnect region 112 formed on an upper surface of the semiconductor substrate 102. The electrical interconnect region 112 comprises multiple conductive interconnect layers, e.g., metallization layers, polysilicon layers, etc. arranged between regions of dielectric material. According to an embodiment, the electrical interconnect region 112 comprises a so-called FEOL (front-end of line) region that is formed on the upper surface of the semiconductor substrate 102 and a so-called called BEOL (back-end of line) region formed on the upper surface of the semiconductor substrate 102 over the FEOL region. The FEOL region is used to form the electrode structures of the devices and provides the lowest level of electrical interconnect of the semiconductor substrate 102. This first-level interconnect can comprise metals such as copper, aluminum, tungsten, nickel, etc., and alloys thereof, crystalline materials such as polysilicon, and metal silicides such as copper silicide, aluminum silicide, nickel silicide, etc. The FEOL region additionally includes barrier layers and passivation layers that are used to protect the structures and prevent metal diffusion of contaminants, respectively. The barrier layers may be formed from a variety of insulators, e.g., SiN, polyimide, etc. The passivation layers may be formed from a variety of metal materials that prevent diffusion, e.g., Ti, TiN, Ta, TaN/Ta, WN, etc. As shown, the FEOL region may additionally include semiconductor material that is formed on the upper surface and incorporated into the electrode structure of the device. More particularly, the FEOL features may include a region of doped type III-V material incorporated into the gate structure and/or a region doped of type III-V material incorporated into the drain structure. The BEOL region is configured to provide electrical interconnections between the devices formed by the FEOL process and to form externally accessible terminals (e.g., bond pads) on an outer surface of the device. The BEOL region comprises dielectric layers and levels of structured metallization. The dielectric layers may comprise silicon dioxide (SiO₂), silicon oxynitride (SiOₓN_{Y}), glass, polymers, etc. The structured metallization may comprise copper, aluminum, tungsten, nickel, etc. embedded into thin barrier or liner material, and alloys thereof. The BEOL (back-end of the line) region further comprises through-vias that provide vertical connections through the dielectric layers. The through-vias may comprise electrically conductive material such as tungsten, nickel, copper, aluminum, etc. In the depicted embodiment, the BEOL comprises a first level of metallization that is formed over the semiconductor substrate 102 and a second level of metallization that is formed over the first level of metallization. Additionally, the BEOL region comprises a first interlayer dielectric (ILD₁), a first intermetal dielectric (IMD₁) and a second interlayer dielectric (ILD₂).

The semiconductor device 100 comprises a plurality of upper-level contact pads 114 formed in the second (uppermost) level of metallization from the BEOL region. The upper-level contact pads 114 form the base of a contact structure that is used for external electrical interconnect of the device. In the depicted cross-section, the semiconductor device 100 comprises a first one 115 of the upper-level contact pads 114. The first one 115 of the upper-level contact pads 114 is electrically connected with a first load terminal of the power semiconductor device 100. In the depicted embodiment, the first load terminal of the power semiconductor device 100 corresponds to a drain terminal of the transistor. The electrical connection is effectuated by a combination of via structures and structured regions of metallization from within the interconnect region. The upper-level contact pads 114 can be configured to as the thickest and/or largest metallization structures of the device so as to accommodate significant mechanical forces, e.g., from soldering, interconnect, needle contact during functional test etc. For example, a thickness of the upper-level contact pads 114 can be in the range of 1 μm to 15 μm and more particularly about 5 μm. Separately or in combination, a width of the upper-level contact pads 114 can be in the range of 100 μm to several mm such as 5 mm die size.

The semiconductor device 100 comprises a passivation structure 116 formed over the electrical interconnect region 112 and over the first one 115 of the upper-level contact pads 114. The passivation structure 116 is a protective structure that mitigates against uptake of moisture or transfer of ions and is configured to prevent contamination and/or out diffusion of the metal from the upper-level contact pads 114. Generally speaking, the passivation structure 116 may be formed from materials such as silicon dioxide (SiO₂), silicon nitride (Si₃N₄), or silicon oxynitride (SiOxNy). The passivation structure 116 may be a multi-layer structure comprising two or more layers of, e.g., silicon dioxide, silicon nitride and silicon oxynitride. In the depicted embodiment, the passivation structure 116 is a multi-layer passivation layer stack comprising a first passivation layer 118 that conformally lines the upper-level contact pads 114, a second passivation layer 120 formed on the first passivation layer and a third passivation layer 122 formed on the second passivation layer 120. According to an embodiment, the first passivation layer 118 is a layer of silicon nitride, the second passivation layer 120 is a layer of silicon dioxide, and the third passivation layer 122 is a layer of silicon nitride. According to an embodiment, the thickness of the first passivation layer 118 is in the range of 50 nm to 150 nm and may be 100 nm in a particular example. According to an embodiment, the thickness of the second passivation layer 120 is in the range of 300 nm to 500 nm and may be 400 nm in a particular example. According to an embodiment, the thickness of the third passivation layer 122 is in the range of 150 nm to 500 nm and may be 300 nm in a particular example.

The semiconductor device 100 comprises an imide layer 124 formed over outer corners of the upper-level contact pads 114. The imide layer 124 exposes a central region of the upper-level contact pads 114. That is, the imide layer 124 is formed around the periphery of the upper-level contact pads 114 and is not formed over a central area of each upper-level contact pads 114. The imide layer 124 provides electrical isolation, prevents unwanted current leakage and provides an outer layer of protection for the semiconductor device 100 and can block particles, etc., from contamination and degradation of the device. The imide layer 124 may be formed from a polyimide and in particular may comprise a thermosetting polyimide. According to an embodiment, a thickness of the imide layer 124 is in the range of 1 μm to 50 μm. More particularly, the thickness of the imide layer 124 may be in the range of 2 μm to 25 μm. More particularly, the thickness of the imide layer 124 may be in the range of 5 μm to 10 μm. More particularly, the thickness of the imide layer 124 may be about 5 μm.

The semiconductor device 100 comprises a plurality of external contact structures 126 that are formed on the upper-level contact pads 114. The external contact structures 126 are formed within openings in the passivation structure 116 in the central portion of the upper-level contact pads 114 and are therefore externally accessible. That is, the external contact structures 126 are formed to protrude through the passivation structure 116. While the cross-sectional view of FIG. 1 shows only one of the external contact structures 126, a plurality of external contact structures 126 may be provided for each of the upper-level contact pads 114, examples of which will be described in further detail below. The external contact structures 126 are configured to provide mechanical strength reinforcement of the upper-level contact pads 114 and to facilitate external electrical connection to an electrical interconnect element, e.g., bond wire, clip, ribbon, bond pad, etc.

Generally speaking, the external contact structures 126 may comprise metals that may be formed by an electroless plating process, such as Ni and alloys thereof. According to an embodiment, the external contact structures comprise a core region 128 that fills the openings in the passivation structure 116 and an outer layer 130 covering the core region. More particularly, the core region 128 may be a region of NiP (nickel phosphorus). Separately or in combination, the outer layer 130 may be a multi-layer structure comprising a first layer of Pd (palladium) that is formed on the core region and a second layer of Au (gold) that is formed on the first layer. According to an embodiment, the thickness of the core region 128 (as measured from the lowest surface that faces the upper-level contact pad to an upper surface opposite from the lowest surface) is in the range of 3 μm to 15 μm. More particularly, the thickness of the core region 128 may be in the range of 5 μm to 10 μm. More particularly, the thickness of the core region 128 may be about 4-5 μm. According to an embodiment, the thickness of the first layer of Pd is in the range of 100 nm to 500 nm and may be about 200-300 nm in a particular example. According to an embodiment, the thickness of the second layer of Au is in the range of 5 nm to 100 nm and may be about 5-10 nm in a particular example.

As shown, the external contact structures 126 are arranged to laterally overlap with the passivation structure 116 in a mushroom-like arrangement, i.e., an arrangement wherein the external contact structures 126 completely fill the openings and extend past the peripheral edge sides of the passivation structure 116 in every direction. Generally speaking, the overlap distance, i.e., the lateral distance between the peripheral edge sides of openings in the multi-layer passivation and the outer edges of the external contact structures may be in the range of 1 μm to 5 μm, more particularly in the range of 1.5 μm to 3 μm, more particularly about 2 μm.

As shown, the external contact structures 126 are arranged such that a lateral gap exists between the outer edges of the external contact structures 126 and the inner edge sides of the imide layer 124. Generally speaking, this lateral separation distance LSD₁ may be in the range of 1 μm to 50 μm, more particularly in the range of 2 μm to 25 μm, more particularly in the range of 5 μm to 15 μm, more particularly about 10 μm. In another embodiment, this lateral gap is eliminated such that the external contact structures 126 contact the inner edge sides of the imide layer 124.

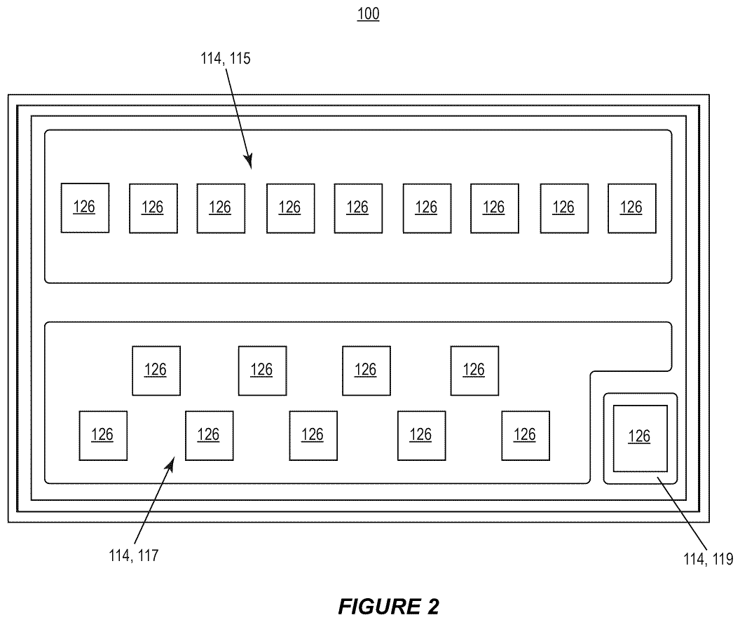

Referring to FIG. 2, a plan-view of the semiconductor device 100 is shown, according to an embodiment. As shown from the plan-view perspective, the semiconductor device 100 comprises multiple upper-level contact pads 114, each of which comprise the external contact structures formed thereon. In particular, the semiconductor device 100 comprises a first one 115 of the upper-level contact pads 114 that is vertically electrically connected with the source terminal of the device (as shown in FIG. 1). Additionally, the semiconductor device 100 comprises a second one 117 of the upper-level contact pads 114 that is vertically electrically connected with the drain terminal of the device and a third one 119 of the upper-level contact pads 114 that is vertically electrically connected with the gate terminal of the device. The vertical electrical connections of the second and third upper-level contact pads 114 may be effectuated in a similar manner to the vertical electrical connection of the first one 115 of the upper-level contact pads 114 as shown in FIG. 1. In addition to the discrete device embodiment shown in FIG. 2, the metallization structure and embodiments disclosed herein are more generally applicable to pad structures for additional device pads, such as logic pads, current sense, temperature sense pads and pads for a substrate compensation circuit and routing of a substrate compensation circuit.

As can be seen, each of the external contact structures 126 have an enclosed shape geometry from a plan-view perspective of the semiconductor device 100. That is, the external contact structures 126 are arranged with a complete lateral boundary that surrounds the edge sides of openings in the passivation structure 116. In the depicted embodiment, the external contact structures 126 have a square shape. More generally, the external contact structures 126 may have a wide variety of geometries, e.g., polygons such as hexagons, octagons, rectangles, triangles, curved shapes such as circles, ellipses, etc. and shapes that avoid acute angles below 90°.

As can be seen, the first one 115 of the upper-level contact pads 114 and the second one 117 of the upper-level contact pads 114 are each arranged with a plurality of the external contact structures 126 formed thereon. Moreover, from the plan-view perspective of the semiconductor device 100 the external contact structures 126 are laterally spaced apart from one another by a gap. Thus, each external contact structure corresponds to a spatially isolated island. Generally speaking, the particular separation distance between two immediately adjacent upper-level contact pads 114 may be in the range of 1 μm to 30 μm, more particularly in the range of 1.5 μm to 15 μm, or more particularly about 2 μm. Such an arrangement may be beneficial and/or preferential, particularly in the case of the load terminals of the device which have significantly large contact area to accommodate the load current, and the contact structures may be beneficial to improve connect ability and mechanical durability with an external connector. FIG. 2 shows just one example of an exemplary pattern of the external contact structures 126. More generally, a variety of patterns may be used, including patterns with asymmetric distributions of the external contact structures 126, patterns with the external contact structures 126 regularly spaced apart from one another, and so forth. The particular pattern may be designed to be compatible with a particular interconnect element, bond pad configuration, etc. Separately or in combination, the semiconductor device 100 may have different geometries and/or numbers of the multiple upper-level contact pads 114 from one is shown, and the external contact structures 126 may be implemented in any of these designs. In one example of this, the semiconductor device 100 may comprise a fourth one of the upper-level contact pads 114 that is separately electrically connected with the source terminal of the device and serves as a sense terminal, wherein this upper-level contact pad comprises one or more of the external contact structures 126.

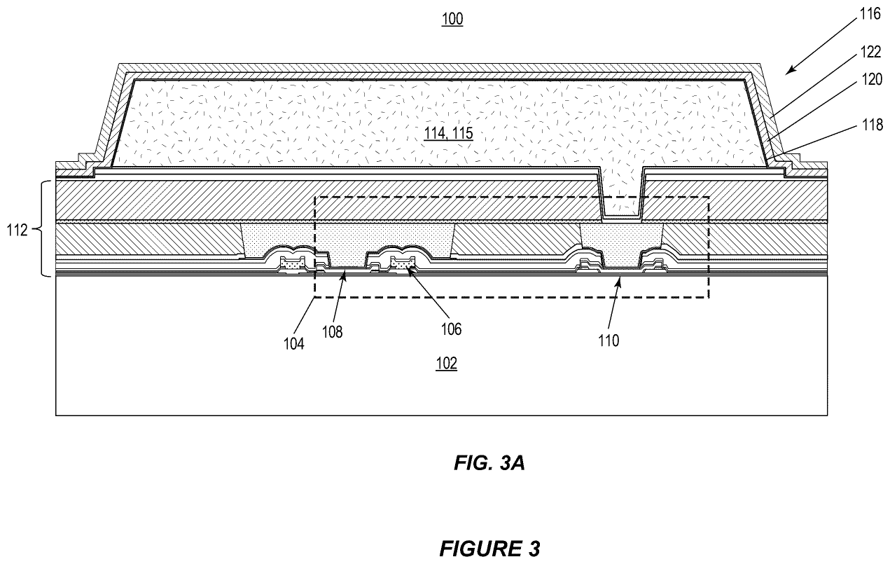

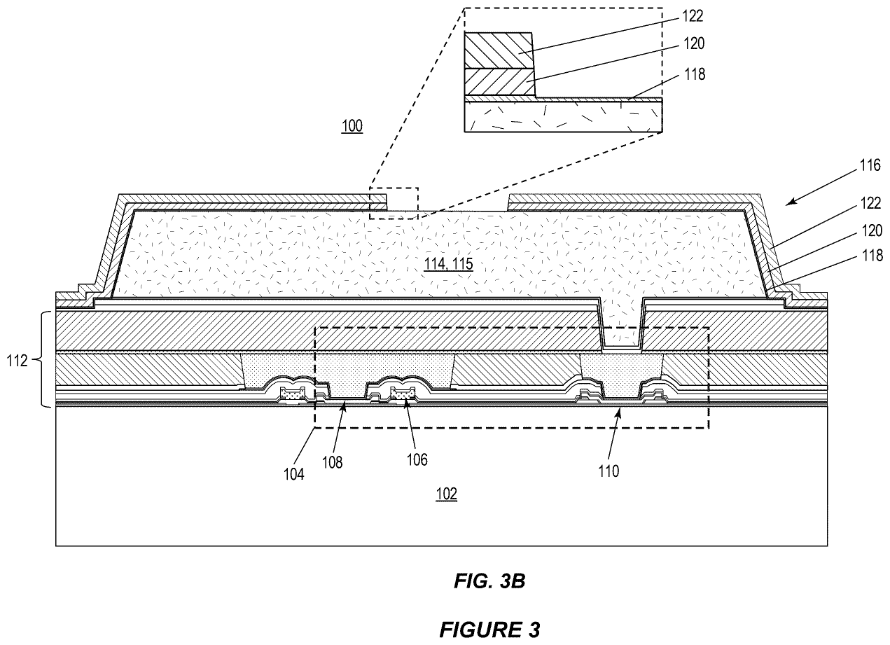

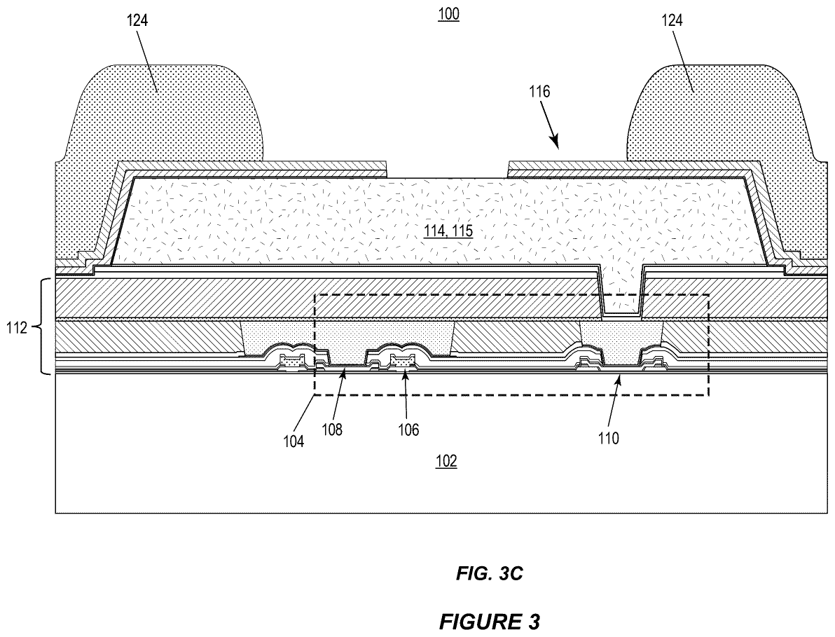

Referring to FIG. 3A, a method of forming the semiconductor device 100 comprises providing the semiconductor substrate 102 and forming the features of the power semiconductor device 100 thereon. Once fabrication of the semiconductor substrate 102 is complete, the interconnect region 112 comprising the FEOL (front-end of line) and the BEOL (back-end of line) region can be formed. This process includes a sequence of depositing, etching, patterning, CMP (chemical mechanical polishing), etc. Once the upper-level contact pads 114 are formed, the passivation structure 116 is formed. Forming the passivation structure 116 may comprise conformally depositing the first passivation layer 118 over the upper-level contact pads 114, then conformally depositing the second passivation layer 120 on the first passivation layer 118, and conformally depositing the third passivation layer 122 on the second passivation layer 120. As a result, the upper-level contact pads 114 become completely covered by the multi-layer passivation comprising the first passivation layer 118, the second passivation layer 120, and the third passivation layer 122. In other embodiments, the upper-level contact pads 114 may become completely covered by any passivation structure 116 with additional or reduced amounts of passivation layers.

Referring to FIG. 3B, a method of forming the semiconductor device 100 comprises partially etching the passivation structure 116 without exposing the upper surface of the upper-level contact pads 114. In particular, an etching process is carried out to form openings that completely penetrate the third passivation layer 122, the second passivation layer 120 and partially penetrate the first passivation layer 118. As shown in the close-up view of the etch, a thickness of the first passivation layer 118 remains on the upper surface of the upper-level contact pads 114. This etching process may comprise a masked etching technique wherein a structured mask (not shown) is provided over the passivation structure 116 and the materials of the passivation structure 116 are removed, e.g., by wet or dry chemical etch, so as to partially remove the first passivation layer 118.

Referring to FIG. 3C, the imide layer 124 is formed over the passivation structure 116 and the outer edges of the upper-level contact pads 114 with a central opening of the imide layer 124 remaining. The imide layer 124 may be formed by a curing process whereby the imide layer 124 is initially applied in a liquid state and heat is applied to the imide layer 124, thereby causing a chemical reaction that crosslinks the polymer chains and transforms the imide into a stable solid. Generally speaking, the curing process may be performed at temperatures of at least 250° C., at least 300° C., at least 350° C., at least 400° C. or more during at least 20 minutes, typically 30 minutes, up to 5 hours. After the imide layer 124 is formed and cured, a further etching process is performed. The further etching process completely removes the remaining part of the passivation structure 116, i.e., the partial thickness of the third passivation layer, thereby completing the openings in the passivation structure 116 and exposing the upper surface of the external contact structures 126. According to this process, the cured imide layer 124 serves as a hardmask structure that protects the semiconductor device 100 from the etchant outside of the upper-level contact pads 114. As mentioned above, the imide layer 124 may have a thickness of at least 1 μm and may be significantly thicker, e.g., 5 μm, 10 μm, etc. At these thickness levels, the imide layer 124 is sufficiently equipped to withstand the etching process. The further etching process may comprise a wet or dry chemical etch.

After forming the imide layer 124 and after completion of opening the passivation (layer), the external contact structures 126 are formed by deposing metal material within the openings of the openings in the passivation structure 116. The external contact structures 126 may be formed by a metal deposition process. According to an embodiment, the external contact structures 126 are formed by an ECD (electrochemical deposition) process.

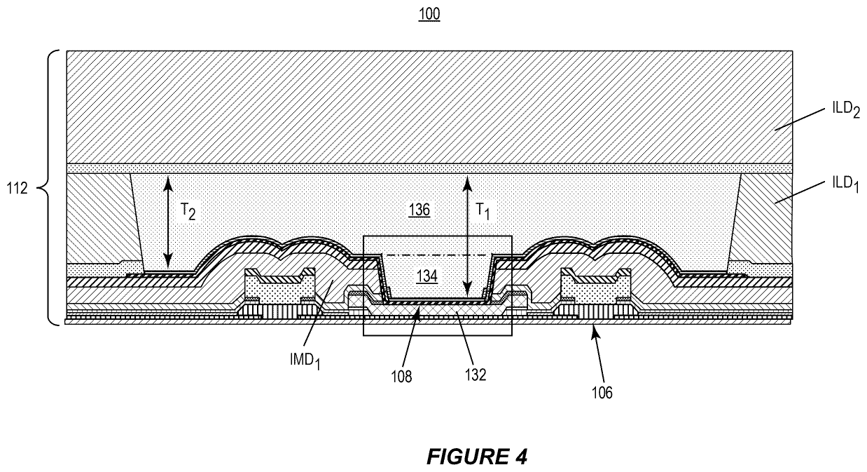

Referring to FIG. 4, a close-up view of the semiconductor device 100 described with reference to FIG. 1 is shown. The close-up view shows the details of a hybrid via-metallization structure that is formed within a lower part of the electrical interconnect region 112 of the device. The hybrid via-metallization structure is formed within a combined opening in the first interlayer dielectric (ILD1) and the first intermetal dielectric (IMD₁) of the device. According to an embodiment, a thickness of the first interlayer dielectric (ILD₁) is in the range of 100 nm to 5 μm. More particularly, the thickness of the first interlayer dielectric (ILD₁) may be in the range of 500 nm to 5 μm. More particularly, the thickness of the first interlayer dielectric (ILD₁) may be about 1 μm. The first interlayer dielectric (ILD₁) may be a multi-layer structure comprising two or more layers of insulators, e.g., SiO₂, SiN, polyimide, etc. More particularly, the first interlayer dielectric (ILD₁) may comprise a layer of nitride (e.g., SiN) arranged between two layers of oxide, e.g., SiO₂ formed by a TEOS (Tetraethyl orthosilicate) process. According to an embodiment, a thickness of the first intermetal dielectric (IMD₁) is in the range of 1 μm to 10 μm. More particularly, the thickness of the first intermetal dielectric (IMD₁) may be about 2 μm. The second interlayer dielectric (ILD₂) may be a single layer or multi-layer structure comprising insulators, e.g., SiO₂, SiN, polyimide, etc.

The hybrid via-metallization structure is in low-ohmic contact with a load terminal of the power semiconductor device 100. In the depicted embodiment, the hybrid via-metallization structure forms a low-ohmic contact with a first load terminal of the power semiconductor device 100, which may correspond to the source terminal. The lower contact pad 132 is formed from a conductive material, e.g., copper, aluminum, tungsten, nickel, etc., alloys thereof, crystalline materials such as polysilicon, or metal silicides such as copper silicide, aluminum silicide, nickel silicide, etc. A thickness of the lower contact pad 132 may be in the range of 50 nm to 1 μm. More particularly, the thickness of the lower contact pad 132 may be about 100 nm to 350 nm.

Referring again to FIG. 1, the device may additionally comprise a second hybrid via-metallization structure that is in low-ohmic contact with a second load terminal of the power semiconductor device 100, which may correspond to the drain terminal. Each of the hybrid via-metallization structures may have the characteristics described herein and may be formed according to any of the techniques described herein. Moreover, the hybrid via-metallization structure shown in FIG. 4 may similarly be contacted with one or more of the upper-level contact pads 114 in a similar manner as the hybrid via-metallization structure shown in FIG. 1. Separately or in combination, the hybrid via-metallization structure shown in FIG. 4 may be used to connect the terminal of the semiconductor device 100 with another device formed on the same semiconductor substrate 102 using the interconnect metallization levels of the interconnect region 112.

Referring again to FIG. 4, the hybrid via-metallization structure is a continuous metal structure that comprises a via portion 134 arranged within a trench in the first interlayer dielectric region and a metallization portion 136 arranged over the via portion 134. That is, the hybrid via-metallization structure is a single structural feature that provides vertical interconnect between a first level metallization and the semiconductor substrate 102 and an interconnect feature that provided electrical routing at the first level metallization level that is formed over the first interlayer dielectric (ILD1). To this end, the hybrid via-metallization structure comprises a via portion 134 arranged within a trench in the first interlayer dielectric (ILD₁) and a metallization portion 136 arranged over the via portion 134 and in between the first intermetal dielectric (IMD₁). The description that the hybrid via-metallization structure is a continuous metal structure means that the hybrid via-metallization structure forms a single region of metal without interfaces between the via portion 134 and the metallization portion 136. As will be explained below, the hybrid via-metallization structure can be formed by a single metal deposition step whereby metal is deposited to form both the via portion 134 and the metallization portion 136. According to an embodiment, the hybrid via-metallization structure comprises Cu. More particularly, the hybrid via-metallization structure may be formed from pure or substantially pure Cu or W. According to an embodiment, a thickness T₁ of the hybrid via-metallization structure is in the range of 500 nm to 10 μm. More particularly, the thickness T₁ of the hybrid via-metallization structure may be in the range of 1 μm to 5 μm. More particularly, the thickness T₁ of the hybrid via-metallization structure may be in the range of 2.5 μm to 3.5 μm. More particularly, the thickness T₁ of the hybrid via-metallization structure may be about 3 μm. In this regard, the thickness T₁ of the hybrid via-metallization structure refers to a distance between a bottom surface of the hybrid via-metallization structure within the trench in the first interlayer dielectric (ILD₁) and an upper surface of the hybrid via-metallization structure opposite from the bottom surface of the hybrid via-metallization structure. As shown, the thickness T₂ of the hybrid via-metallization structure is reduced from this maximum thickness in the metallization portion 136 wherein the metal structure overlaps with the first intermetal dielectric (IMD₁). In this portion, the thickness T₂ of the hybrid via-metallization structure may be, e.g., between 75% and 25% of the maximum thickness values as indicated above.

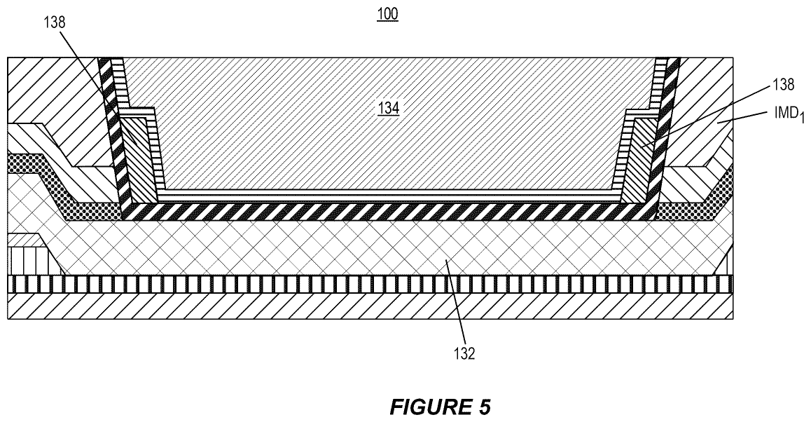

Referring to FIG. 5, a close-up view of the semiconductor device 100 is shown in the vicinity of the trench in the first interlayer dielectric (ILD₁) and the via portion 134 of the hybrid via-metallization structure filling the trench in the first intermetal dielectric (IMD₁). According to the depicted embodiment, the semiconductor device 100 comprises spacer dielectric regions 138 arranged along sidewalls of the trench. The spacer dielectric regions 138 occupy corner regions of the trench between the sidewalls of the trench and the bottom surface of the trench. The bottom surface of the trench in between the spacer dielectric regions 138 is exposed from the spacer dielectric regions 138, thereby facilitating electrical contact between a lower planar surface of the of the hybrid via-metallization structure that extends between the spacer dielectric regions 138 along at bottom of the trench. As shown, the spacer dielectric regions 138 may extend vertically only along a portion of the opposite facing sidewalls of the trench, with the hybrid via-metallization structure extending along the remaining portions. The spacer dielectric regions 138 improve contact integrity between the hybrid via-metallization structure and the lower contact pad 132 by facilitating a more planar contact interface. That is, the spacer dielectric regions 138 mitigate the potential for curvature and gaps resulting from imperfect conformality of the deposited metal at the corners of the trench. Consequently, the spacer dielectric regions 138 facilitate narrower contact structures and hence greater integration density while using the hybrid via-metallization structure. The spacer dielectric regions 138 may be formed from any type of dielectric material, e.g., such as silicon dioxide (SiO₂), silicon nitride (Si₃N₄), or silicon oxynitride (SiOxNy). According to an embodiment, the spacer dielectric regions 138 are formed from a nitride material, such as silicon nitride. According to an embodiment, a thickness of the spacer dielectric regions 138 is in the range of 0.1 μm to 2 μm. More particularly, the thickness of the spacer dielectric regions 138 may be in the range of 50 nm to 200 nm. According to an embodiment, a height of the spacer dielectric regions 138 is in the range of 50 nm to 5 μm. More particularly, the height of spacer dielectric regions 138 may be in the range of 1 μm to 2.5 μm.

A method for forming the semiconductor device 100 comprising the hybrid via-metallization structure(s) with the optional spacer dielectric regions will now be described. According to an embodiment, the hybrid via-metallization structures are formed by a dual damascene process. A damascene process refers to a technique for forming interconnect metallization in semiconductor devices whereby the metallization is deposited into trenches that are formed, e.g., by etching, an intermetal dielectric region. The damascene process is preferable for forming metallization from copper and copper-based alloys, which are more difficult or impossible to form using other techniques. The dual damascene process refers to a combined process whereby the interconnect metallization and the underlying via structure for contacting the interconnect metallization are formed together in a in a single processing step.

An embodiment of forming the hybrid via-metallization structures includes the following. Initially, first intermetal dielectric (IMD₁) is formed is formed over the upper surface of the semiconductor substrate 102. This may be done using a deposition technique such as a TEOS (tetraethyl orthosilicate) deposition process. Subsequently, the first interlayer dielectric (ILD₁) is formed. This may be done using a deposition technique such as a TEOS (tetraethyl orthosilicate) deposition process. Subsequently, a combined opening that forms the trench in the first intermetal dielectric (IMD₁) and the first interlayer dielectric (ILD₁) is formed. This may be done by a masked etching technique, for example. Subsequently, one or more layers of material are conformally deposited along the sidewalls and bottom of the trench. These layers may be thin layers, e.g., layers having a thickness of between 10 nm and 1 μm, that serve different purposes. According to an embodiment, a barrier layer, which may comprise Ta or TaN or a combination of TaN and Ta for example, is conformally deposited along the sidewalls and bottom of the trench, so as to prevent diffusion between the first interlayer dielectric (ILD₁) and the metal of the hybrid via-metallization structure (IMD₁). Subsequently, a seed layer is deposited so as to facilitate deposition of a metal thereon. The seed layer may comprise a conductive metal, e.g., copper and alloys thereof. According to an embodiment, the seed layer is a layer of Al-doped copper. Al-doped copper may enhance the lifetime reliability of the hybrid via-metallization structures. After forming the layers along the sidewalls and bottom of the trench, metal is deposited into the combined opening so as form the via portion 134 within the trench and the metallization portion 136 extending over the first interlayer dielectric (ILD1) outside of the trench. Subsequently, a planarization step may be performed to make the upper surface of the hybrid via-metallization structure with the upper surface of the intermetal dielectric region. This may be done using a chemical mechanical polishing (CMP) process, for example.

An embodiment of forming the spacer dielectric regions 138 along sidewalls of the trench in the first interlayer dielectric includes the following. After forming the combined opening and before forming the seed layer, a dielectric material, e.g., SiN, may be deposited in the combined opening. The dielectric material may be formed to partially or completely fill the trench. Subsequently, a central part of the dielectric material is etched, thereby forming the spacer dielectric regions 138. This may be done by a masked etching technique or a maskless etching technique, for example. After forming the spacer dielectric regions 138, the seed layer may be formed, followed by the deposition of the metal into the combined opening.

Although the present disclosure is not so limited, the following numbered examples demonstrate one or more aspects of the disclosure.

Example 1. A semiconductor device, comprising: a semiconductor substrate; a power semiconductor device monolithically formed in the semiconductor substrate; an electrical interconnect region formed on an upper surface of the semiconductor substrate; a first one of the upper-level contact pads formed in an uppermost level of metallization from the electrical interconnect region, the first one of the upper-level contact pads being electrically connected with a first load terminal of the power semiconductor device; a passivation structure formed over the electrical interconnect region and partially covering the first one of the upper-level contact pads; an imide layer formed over outer corners of the first one of the upper-level contact pads and exposing a central region of the first one of the upper-level contact pads, a plurality of external contact structures that are exposed from openings in the passivation structure in the central region of the first one of the upper-level contact pads, wherein the external contact structures each comprise NiP.

Example 2. The semiconductor device of example 1, wherein from a plan-view perspective of the semiconductor device each of the external contact structures has an enclosed shape geometry.

Example 3. The semiconductor device of example 2, wherein from the plan-view perspective of the semiconductor device the external contact structures are laterally spaced apart from one another.

Example 4. The semiconductor device of example 1, wherein from a cross-sectional perspective of the semiconductor device each of the external contact structures laterally overhangs past outer edges of the openings in the passivation structure.

Example 5. The semiconductor device of example 4, wherein from the cross-sectional perspective of the semiconductor device each of the external contact structures has a mushroom geometry.

Example 6. The semiconductor device of example 4, wherein from the cross-sectional perspective of the semiconductor device a lateral gap is provided between the imide layer 124 and the external contact structures.

Example 7. The semiconductor device of example 6, wherein the lateral gap is at least 2 μm.

Example 8. The semiconductor device of example 1, wherein the passivation structure is a multi-layer passivation structure that comprises two or more layers of silicon dioxide, silicon nitride, or silicon oxynitride.

Example 9. The semiconductor device of example 1, wherein the external contact structures each comprise a core region of NiP and one or more metallization layers formed over the core region.

Example 10. The semiconductor device of example 9, wherein the one or more metallization layers formed over the core region comprise a first layer of Pd and a second layer of Au.

Example 11. The semiconductor device of example 1, wherein the power semiconductor device is a power transistor, and wherein the first load terminal is a source terminal of the power transistor.

Example 12. The semiconductor device of example 11, wherein the semiconductor device further comprises a second upper-level contact pad formed in the uppermost level of metallization from the electrical interconnect region, the first one of the upper-level contact pads being electrically connected with a second load terminal of the power semiconductor device, and wherein the second load terminal is a drain terminal of the power transistor.

Example 13. A method of forming a semiconductor device, comprising: providing a semiconductor substrate with a power semiconductor device monolithically formed in the semiconductor substrate; forming an electrical interconnect region formed on an upper surface of the semiconductor substrate, the electrical interconnect region comprising a first one of the upper-level contact pads formed in an uppermost level of metallization from the electrical interconnect region and being electrically connected with a first load terminal of the power semiconductor device; forming a passivation structure over the electrical interconnect region and partially covering the first one of the upper-level contact pads; forming an imide layer over corners of the first one of the upper-level contact pads and exposing a central region of the first one of the upper-level contact pads, forming a plurality of external contact structures that are exposed from openings in the passivation structure in the central region of the first one of the upper-level contact pads, wherein the external contact structures each comprise NiP.

Example 14. The method of example 13, wherein the imide layer is formed before forming the plurality of external contact structures.

Example 15. The method of example 14, wherein forming the imide layer comprises curing the imide layer at a temperature of at least 300° C.

Example 16. The method of example 13, wherein the imide layer 124 has a thickness of at least 5 μm.

Example 17. The method of example 13, wherein from a plan-view perspective of the semiconductor device each of the external contact structures has an enclosed shape geometry.

Example 18. The method of example 17, wherein from the plan-view perspective of the semiconductor device the external contact structures are laterally spaced apart from one another.

Example 19. The method of example 13, wherein from a cross-sectional perspective of the semiconductor device each of the external contact structures laterally overhangs past outer edges of the openings in the passivation structure.

Example 20. The method of example 19, wherein from the cross-sectional perspective of the semiconductor device each of the external contact structures has a mushroom geometry.

Example 21. The method of example 20, wherein from the cross-sectional perspective of the semiconductor device a lateral gap is provided between the imide layer and the external contact structures.

Example 22. The method of example 21, wherein the lateral gap is at least 2 μm.

Example 23. The method of example 13, wherein the passivation structure is a multi-layer passivation structure that comprises two or more layers of silicon dioxide, silicon nitride, or silicon oxynitride.

Example 24. The method of example 13, wherein the external contact structures each comprise a core region of NiP and one or more metallization layers formed over the core region.

Example 25. The method of example 24, wherein the one or more metallization layers formed over the core region comprise a first layer of Pd and a second layer of Au.

Example 26. The method of example 13, wherein the power semiconductor device is a power transistor, and wherein the first load terminal is a source terminal of the power transistor.

Example 27. The method of example 26, wherein the semiconductor device 100 further comprises a second upper-level contact pad formed in the uppermost level of metallization from the electrical interconnect region, the first one of the upper-level contact pads being electrically connected with a second load terminal of the power semiconductor device, and wherein the second load terminal is a drain terminal of the power transistor.

Example 28. A semiconductor device, comprising: a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; and a high-electron mobility transistor monolithically formed in the semiconductor substrate and comprising first and second load terminals; a first interlayer dielectric region formed over an upper surface of the semiconductor substrate; a first interconnect metallization level formed over the first interlayer dielectric region; and a hybrid via-metallization structure in low-ohmic contact with the first load terminal of the high-electron mobility transistor, wherein the hybrid via-metallization structure is a continuous metal structure that comprises a via portion arranged within a trench in the first interlayer dielectric region and a metallization portion arranged over the via portion.

Example 29. The semiconductor device of claim 28, wherein the hybrid via-metallization structure is a copper structure.

Example 30. The semiconductor device of claim 29, further comprising a seed layer that lines sidewalls and a bottom of the trench, wherein the seed layer is a layer of Al-doped copper.

Example 31. The semiconductor device of claim 29, wherein a thickness of the hybrid via-metallization structure is between 1 μm and 5 μm.

Example 32. The semiconductor device of example 31, wherein the thickness of the hybrid via-metallization structure is between 2.5 μm and 3.5 μm.

Example 33. The semiconductor device of example 28, wherein the channel layer is a layer of GaN or AlGaN, wherein the barrier layer is a region of AlGaN with a higher aluminium content than the channel layer.

Example 34. The semiconductor device of example 33, wherein the high-electron mobility transistor is configured as a power transistor, and wherein the semiconductor device further comprises a second switching device that is configured to control a switching operation of the high-electron mobility transistor.

Example 35. The semiconductor device of example 34, further comprising a second hybrid via-metallization structure in low-ohmic contact with a terminal of the second switching device.

Example 36. The semiconductor device of example 1, further comprising spacer dielectric regions arranged along sidewalls of the trench, wherein the hybrid via-metallization structure comprises a lower planar surface that extends between the spacer dielectric regions along a bottom of the trench.

Example 37. The semiconductor device of example 36, wherein the spacer dielectric regions are regions of SiN.

Example 38. A method of forming a semiconductor device, the method comprising: providing semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; monolithically forming a high-electron mobility transistor in the semiconductor substrate and comprising first and second load terminals; forming a first interlayer dielectric region over an upper surface of the semiconductor substrate; forming a first interconnect metallization level over the first interlayer dielectric region; and forming a hybrid via-metallization structure in low-ohmic contact with the first load terminal of the high-electron mobility transistor, wherein the hybrid via-metallization structure is a continuous metal structure that comprises a via portion arranged within a trench in the first interlayer dielectric region and a metallization portion arranged over the via portion.

Example 39. The method of example 38, wherein the hybrid via-metallization structure is a copper structure.

Example 40. The method of example 39, further comprising forming a seed layer that lines sidewalls and a bottom of the trench before forming the hybrid via-metallization structure, wherein the seed layer is a layer of Al-doped copper.

Example 41. The method of example 40, wherein a thickness of the hybrid via-metallization structure is between 2.5 μm and 3.5 μm.

Example 42. The method of example 38, wherein forming the hybrid via-metallization structure comprises a dual damascene process.

Example 43. The method of example 42, wherein the dual damascene process comprises: depositing the first interlayer dielectric region over the upper surface of the semiconductor substrate forming the trench in the first interlayer dielectric region; depositing a seed layer that lines a bottom a sidewalls of the trench; depositing metal that fills the trench and covers a portion of the first interlayer dielectric region outside of the trench.

Example 44. The method of example 43, further comprising forming spacer dielectric regions arranged along sidewalls of the trench in the first interlayer dielectric region.

Example 45. The method of example 44, further comprising forming spacer dielectric regions arranged along sidewalls of the trench, wherein the hybrid via-metallization structure comprises a lower planar surface that extends between the spacer dielectric regions along a bottom of the trench.

Example 46. The method of example 45, wherein the spacer dielectric regions are regions of SiN.

Example 47. The method of example 45, wherein forming the spacer dielectric regions comprises, after forming the trench and before depositing the seed layer: depositing a dielectric material within the trench; etching a central part of the dielectric material thereby forming the spacer dielectric regions at corners between the sidewalls of the trench in the first interlayer dielectric region and bottom of the trench in the first interlayer dielectric region.

The semiconductor devices disclosed herein can be formed in a wide variety of device technologies that utilize a wide variety of semiconductor materials. Examples of such materials include, but are not limited to, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), etc.

The semiconductor devices disclosed herein may be configured as a vertical device, which refers to a device that conducts a load current between opposite facing main and rear surfaces of the die. Alternatively, the semiconductor devices may be configured as a lateral device, which refers to a device that conducts a load current parallel to a main surface of the die.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein.

What is claimed is:

1. A semiconductor device, comprising:
a semiconductor substrate;
a power semiconductor device monolithically formed in the semiconductor substrate;
an electrical interconnect region formed on an upper surface of the semiconductor substrate;
a first upper-level contact pad formed in an uppermost level of metallization from the electrical interconnect region, the first upper-level contact pad being electrically connected with a first load terminal of the power semiconductor device;
a passivation structure formed over the electrical interconnect region and partially covering the first upper-level contact pad;
an imide layer formed over outer corners of the first upper-level contact pad and exposing a central region of the first upper-level contact pad; and
a plurality of external contact structures that are exposed from openings in the passivation structure in the central region of the first upper-level contact pad,
wherein the external contact structures each comprise NiP.

2. The semiconductor device of claim 1, wherein from a plan-view perspective of the semiconductor device each of the external contact structures has an enclosed shape geometry.

3. The semiconductor device of claim 2, wherein from the plan-view perspective of the semiconductor device the external contact structures are laterally spaced apart from one another.

4. The semiconductor device of claim 1, wherein from a cross-sectional perspective of the semiconductor device each of the external contact structures laterally overhangs past outer edges of the openings in the passivation structure.

5. The semiconductor device of claim 4, wherein from the cross-sectional perspective of the semiconductor device each of the external contact structures has a mushroom geometry.

6. A semiconductor device, comprising:
a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface;
a high-electron mobility transistor monolithically formed in the semiconductor substrate and comprising first and second load terminals;
a first interlayer dielectric region formed over an upper surface of the semiconductor substrate;
a first interconnect metallization level formed over the first interlayer dielectric region; and
a hybrid via-metallization structure in low-ohmic contact with the first load terminal of the high-electron mobility transistor,
wherein the hybrid via-metallization structure is a continuous metal structure that comprises a via portion arranged within a trench in the first interlayer dielectric region and a metallization portion arranged over the via portion.

7. The semiconductor device of claim 6, wherein the hybrid via-metallization structure is a copper structure.

8. The semiconductor device of claim 7, further comprising a seed layer that lines sidewalls and a bottom of the trench, wherein the seed layer is a layer of Al-doped copper.

9. The semiconductor device of claim 6, wherein the channel layer is a layer of GaN or AlGaN, wherein the barrier layer is a region of AlGaN with a higher aluminium content than the channel layer.

10. The semiconductor device of claim 6, further comprising spacer dielectric regions arranged along sidewalls of the trench, wherein the hybrid via-metallization structure comprises a lower planar surface that extends between the spacer dielectric regions along a bottom of the trench.

11. The semiconductor device of claim 10, wherein the spacer dielectric regions are regions of SiN.

12. A method of forming a semiconductor device, the method comprising:
providing semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface;
monolithically forming a high-electron mobility transistor in the semiconductor substrate and comprising first and second load terminals;
forming a first interlayer dielectric region over an upper surface of the semiconductor substrate;
forming a first interconnect metallization level over the first interlayer dielectric region; and
forming a hybrid via-metallization structure in low-ohmic contact with the first load terminal of the high-electron mobility transistor,
wherein the hybrid via-metallization structure is a continuous metal structure that comprises a via portion arranged within a trench in the first interlayer dielectric region and a metallization portion arranged over the via portion.

13. The method of claim 12, wherein the hybrid via-metallization structure is a copper structure.

14. The method of claim 13, further comprising forming a seed layer that lines sidewalls and a bottom of the trench before forming the hybrid via-metallization structure, wherein the seed layer is a layer of Al-doped copper.

15. The method of claim 12, wherein forming the hybrid via-metallization structure comprises a dual damascene process.

16. The method of claim 15, wherein the dual damascene process comprises:
depositing the first interlayer dielectric region over the upper surface of the semiconductor substrate
forming the trench in the first interlayer dielectric region;
depositing a seed layer that lines a bottom a sidewalls of the trench; and
depositing metal that fills the trench and covers a portion of the first interlayer dielectric region outside of the trench.

17. The method of claim 16, further comprising forming spacer dielectric regions arranged along sidewalls of the trench in the first interlayer dielectric region.

18. The method of claim 17, further comprising forming spacer dielectric regions arranged along sidewalls of the trench, wherein the hybrid via-metallization structure comprises a lower planar surface that extends between the spacer dielectric regions along a bottom of the trench.

19. The method of claim 18, wherein the spacer dielectric regions are regions of SiN.

20. The method of claim 18, wherein forming the spacer dielectric regions comprises, after forming the trench and before depositing the seed layer:
depositing a dielectric material within the trench; and
etching a central part of the dielectric material thereby forming the spacer dielectric regions at corners between the sidewalls of the trench in the first interlayer dielectric region and bottom of the trench in the first interlayer dielectric region.
